(19) United States
(12) Patent Application Publication
(10) Pub. No.: US 2015/0264797 A1
(43) Pub. Date: Sep. 17, 2015

(54) ELECTRONIC APPARATUS

(71) Applicant: KABUSHIKI KAISHA TOSHIBA, Tokyo (JP)

(72) Inventors: Akihiko HAPPOYA, Oume Tokyo (JP); Yuichi SATO, Kiyose Tokyo (JP); Daigo SUZUKI, Kawasaki Kanagawa (JP)

(21) Appl. No.: 14/445,583

(22) Filed: Jul. 29, 2014

(30) Foreign Application Priority Data
Mar. 14, 2014 (JP) 2014-051393

(51) Int. Cl. H05K 1/02; H05K 1/11; H05K 1/18

(52) U.S. Cl. CPC H05K 1/023; H05K 1/181; H05K 1/116; H05K 1/0298; H05K 2201/10734

(57) ABSTRACT

An electronic apparatus includes a first substrate, an electronic component mounted on a first surface of the first substrate, a plurality of first lands on a second surface of the first substrate that is opposite the first surface, the first lands electrically connected to the electronic component and arranged at a first interval, and a plurality of second lands on the second surface of the first substrate and surrounding the first lands, the second lands arranged at a second interval that is smaller than the first interval.

### CROSS-REFERENCE TO RELATED APPLICATION

This application is based upon and claims the benefit of priority from Japanese Patent Application No. 2014-051393, filed Mar. 14, 2014, the entire contents of which are incorporated herein by reference.

### FIELD

Embodiments described herein relate to an electronic apparatus capable of preventing EMI (electromagnetic interference).

### BACKGROUND

A semiconductor package or a semiconductor module on which communication system units are mounted is required to have a shield structure for preventing EMI. To satisfy such a requirement, such a semiconductor module or an electronic unit, which is mounted on a surface of a semiconductor substrate or a printed circuit board, is covered by metal for shielding.

### DESCRIPTION OF THE DRAWINGS

FIG. 1 is a cross-sectional view of an electronic apparatus according to an embodiment.

FIG. 2 is a cross-sectional view taken along a line II-II in FIG. 1.

FIG. 3 is a cross-sectional view of the electronic apparatus according to the embodiment mounted on a substrate.

FIG. 4 is a cross-sectional view taken along a line IV-IV in FIG. 3.

FIG. 5 is a cross-sectional view illustrating a part of a first modification of the embodiment.

FIG. 6 is a cross-sectional view illustrating a part of a second modification of the embodiment.

FIG. 7 is a cross-sectional view illustrating a third modification of the embodiment.

FIG. 8 is a cross-sectional view illustrating a fourth modification of the embodiment, and another example of the arrangement of lands.

FIG. 9 is a cross-sectional view illustrating a fifth modification of the embodiment, and another example of the arrangement of lands.

### DETAILED DESCRIPTION

Embodiments provide an electronic apparatus capable of suppressing electromagnetic interference.

In general, according to one embodiment, an electronic apparatus includes a first substrate, an electronic component mounted on a first surface of the first substrate, a plurality of first lands on a second surface of a first substrate that is opposite the first surface, the first lands electrically connected to the electronic component and arranged at a first interval, and a plurality of second lands on the second surface of the first substrate and surrounding the first lands, the second lands arranged at a second interval that is smaller than the first interval.

In an LGA (land grid array) package or a BGA (ball grid array) package which handles high frequency signals, for example, an electronic unit is arranged on a front surface of a substrate, and the electronic unit is covered by a resin. Further, the front surface and side surfaces which are made of a resin are covered by a shield member made of metal, silver paste, a plating or a sputtered material so as to suppress EMI. However, a back surface side of the package is not covered by a shield member. Further, there is a gap between the package and a mother board, and EMI is generated through this gap. Recently, it has been observed that frequency of signals processed through the electronic apparatus is becoming higher thus giving rise to a possibility of high-frequency signal leaks through an extremely small gap. To cope with such drawbacks, there has been a demand for an electronic apparatus which may suppress EMI more reliably.

Hereinafter, embodiments are explained with reference to the drawings. In the drawings, identical portions are depicted by the same symbols.

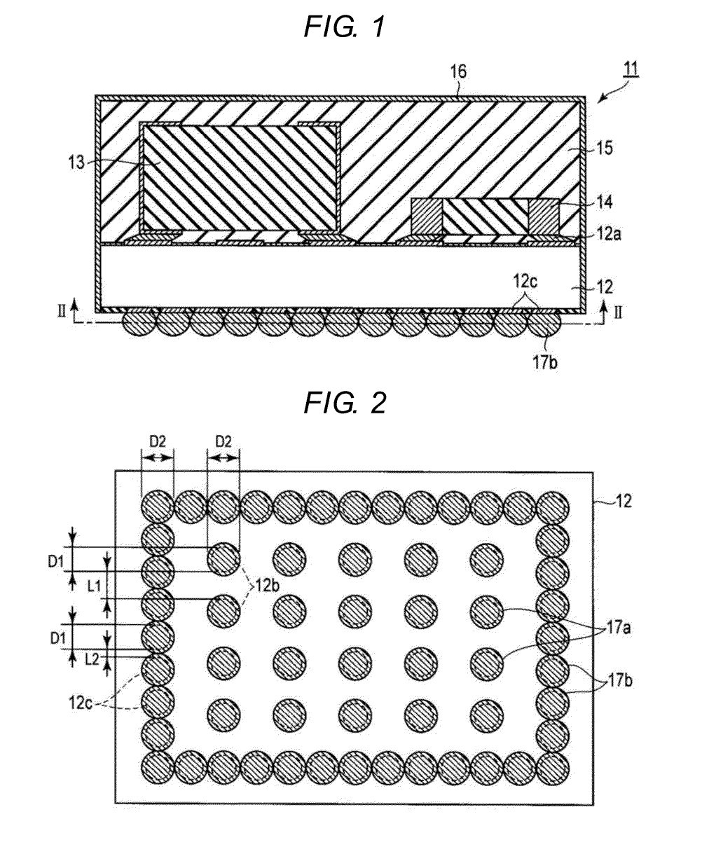

FIG. 1 illustrates an electronic apparatus according to the embodiment. In FIG. 1, an example is described where the electronic apparatus according to the embodiment is applied to a BGA package.

As illustrated in FIG. 1, in a semiconductor module 11 which is a BGA package, a plurality of electronic units 13, 14 are mounted on a front surface (first surface) of a substrate 12. That is, the electronic units 13, 14 are electrically and mechanically connected to a plurality of lands 12a formed on the front surface of the substrate 12 by soldering. The electronic units 13, 14 are covered by, for example, a resin 15 which is formed on the front surface of the substrate 12 by molding. A front surface and side surfaces of the resin 15 and side surfaces of the substrate 12 are integrally covered by a shield member 16. The shield member 16 is formed of a metal plate, or a metal layer or a metal film formed by a silver paste, a plating or sputtered material, for example.

In addition, as illustrated in FIG. 1 and FIG. 2, a plurality of first lands 12b are arranged on a center portion of a back surface (second surface) of the substrate 12. The first lands 12b are electrically connected to the plurality of lands 12a formed on the front surface of the substrate 12 via through-holes or through-hole vias not illustrated in the drawing, for example. An interval (first interval, for example) between the first lands 12b is set to L1.

A plurality of second lands 12c are arranged on the back surface of the substrate 12 around the plurality of first lands 12b. The second lands 12c surround the first lands 12b. An interval (second interval, for example) L2 between the second lands 12c is set smaller than the mutual interval L1 between the first lands 12b (L1>L2).

To be more specific, for example, the first land 12b and the second land 12c have the same diameter D1. A first solder ball 17a formed on the first land 12b and a second solder ball 17b formed on the second land 12c have the same diameter D2. The diameter D2 of the first and second solder balls 17a, 17b is set larger than the diameter D1 of the first and second lands 12b, 12c (D2>D1). In such a state, the interval L1 between the first lands 12b is set to a distance which prevents the first solder balls 17a formed on the first lands 12b and arranged adjacent to each other from being brought into contact with each other.

On the other hand, the interval L2 between the second lands 12c is set to a distance which brings the second solder balls 17b formed on second lands 12c and arranged adjacent to each other into contact with each other or allows the second solder balls 17b formed on second lands 12c and arranged adjacent to each other to be brought into with each other. FIG. 1 and FIG. 2 show a state where the second solder balls 17b arranged adjacent to each other are brought into contact with each other so that the second solder balls 17b are electrically short-circuited with each other.

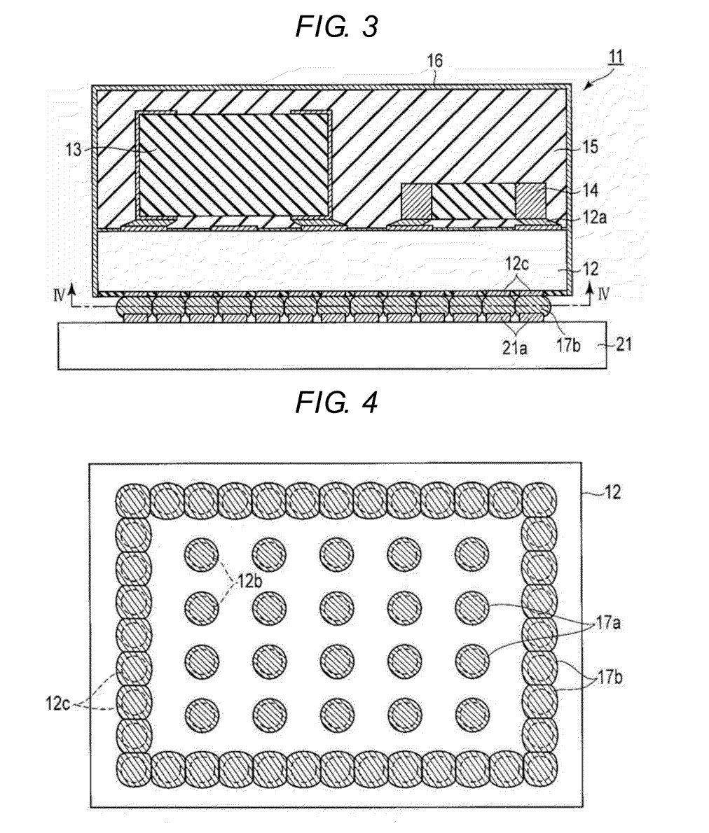

As illustrated in FIG. 3 and FIG. 4, the semiconductor module 11 having the above-mentioned configuration is mounted on a mother board 21. That is, for mounting the semiconductor module 11 on the mother board 21, third lands not illustrated in the drawing which have the same diameter and the same interval as the first lands 12b formed on the semiconductor module 11, and fourth lands 21a which have the same diameter and the same interval as the second lands 12c formed on the semiconductor module 11, are formed on a front surface of the mother board 21, for example.

The first and second solder balls 17a, 17b of the semiconductor module 11 are mounted on the third and fourth lands 21a of the mother board 21 respectively. Thereafter, the first and second solder balls 17a, 17b are reflowed so that the first lands 12b and the third lands are electrically and mechanically connected with each other by the first solder balls 17a, while the second lands 12c and the fourth lands 21a are electrically and mechanically connected with each other by the second solder balls 17b. At this stage of the operation, the plurality of second solder balls 17b formed on the plurality of second lands 12c are deformed and hence, as illustrated in FIG. 3 and FIG. 4, a gap formed between a back surface of the substrate 12 and a front surface of the mother board 21 is closed by the second solder balls 17b.

Further, some of the plurality of second lands 12c or some of the fourth lands 21a are grounded so that a potential of the plurality of second solder balls 17b is held at a ground potential. Accordingly, the back surface of the substrate 12 is shielded from EMI by the second solder balls 17b.

According to the above-mentioned embodiment, the semiconductor module 11 includes: the first lands 12b which are formed on the back surface of the substrate 12 at the first interval L1; and the second lands 12c which are formed on the back surface of the substrate 12 at the second interval L2 which is larger than the first interval L1, and an interval between the second solder balls 17b which are arranged adjacent to each other and are formed on the second lands 12c arranged adjacent to each other is set to a distance which brings the second solder balls 17b formed on second lands 12c and arranged adjacent to each other into contact with each other or allows the second solder balls 17b formed on second lands 12c and arranged adjacent to each other to be brought into contact with each other. Accordingly, when the semiconductor module 11 is mounted on the mother board 21, the second solder balls 17b formed on the second lands 12c are brought into contact with each other so that the second solder balls 17b may surround the first lands 12b and the first solder balls 17a. Due to such a configuration, a gap formed between the mother board 21 and the semiconductor module 11 may be closed by the second solder balls 17b and hence, the electronic apparatus may acquire a sufficient shield effect whereby the electronic apparatus may suppress EMI.

Further, the shield structure according to the embodiment which uses the second solder balls 17b may be achieved by merely setting the interval L2 between the second lands 12c smaller than the interval L1 between the first lands 12b. Accordingly, an increase of manufacturing cost may be suppressed.

Although the above-mentioned embodiment has been explained with respect to the semiconductor module 11 having the BGA structure, this embodiment is not limited to such a semiconductor module 11, and the embodiment is also applicable to a semiconductor module having the LGA structure which has no solder balls upon shipping a product, for example. Even when this embodiment is applied to the semiconductor module having the LGA structure, by setting the first and second lands 12b, 12c such that the relationship substantially equal to the relationship described in the above-mentioned relationship is satisfied, in a state where the semiconductor module 11 is mounted on the mother board, the first solder balls 17a may be surrounded by the second solder balls 17b. Accordingly, such a semiconductor module may also acquire the substantially same advantageous effect as the semiconductor module 11 according to the above-mentioned embodiment.

### (Modification)

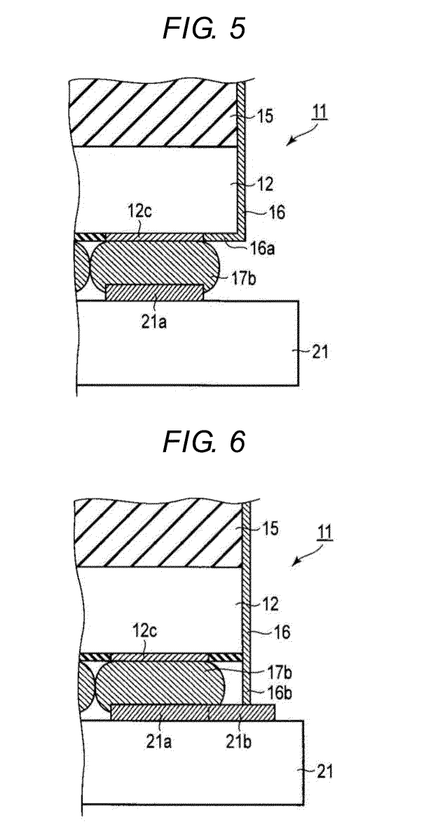

FIG. 5 illustrates a first modification of the embodiment.

In the above-mentioned embodiment, the shield member 16 covers the side surfaces of the resin 15 and the side surfaces of the substrate 12. In the first modification, at least a portion of an end portion of a shield member 16 has an extending portion 16a which covers a back surface of the substrate 12. The extending portion 16a is electrically and mechanically connected with a third land 12c on a back surface of the substrate 12. Accordingly, a potential of the shield member 16 is set to a ground potential together with second solder balls 17b. Due to such a configuration, the whole semiconductor module 11 may be covered by the shield member 16 and the second solder balls 17b and hence, a shield effect may be enhanced whereby EMI may be suppressed.

FIG. 6 illustrates a second modification of the embodiment.

In the second modification, at least some of a plurality of fourth lands 21a formed on a mother board 21 have an extending portion 21b which extends from the fourth land 21a. Further, at least a portion of an end portion of a shield member 16 has an extending portion 16b which extends in the direction toward a mother board 21, and the extending portion 16b is electrically and mechanically connected to the extending portion 21b of the fourth land 21a. Due to such a configuration, a potential of the shield member 16 is set to a ground potential together with second solder balls 17b, and a gap formed between a substrate 12 and the mother board 21 may be more reliably covered by the shield member 16. Accordingly, a shield effect may be enhanced so that EMI may be suppressed.

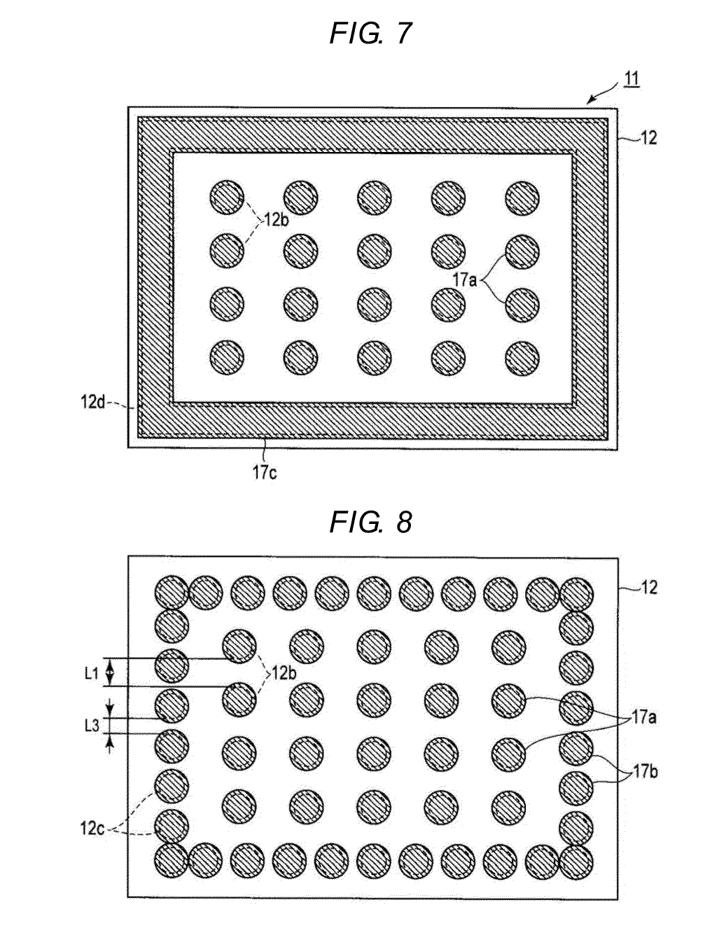

FIG. 7 illustrates a third modification of the embodiment.

In the embodiment, and in the first and second modifications, the second solder balls 17b are formed on the plurality of second lands 12c respectively. In the third modification, a semiconductor module is configured such that a continuous pattern 12d which integrally surrounds a plurality of first lands 12b is formed around the plurality of first lands 12b in place of the plurality of second lands 12c, and a solder layer, for example, a solder paste 17c is continuously formed on the pattern 12d.

Thus, in the third modification, a gap formed between a substrate 12 and a mother board 21 is covered by the continuous solder paste 17c. Accordingly, a shield effect may be enhanced so that EMI may be suppressed.

The second solder balls 17b are brought into contact with each other without forming a gap between the second solder balls 17b in the embodiment, and the first to second modifications, and the continuously formed solder paste 17c is used in the third modification. However, the present disclosure is not limited to the above-mentioned embodiment and modifications. For example, according to a frequency which the semiconductor module 11 handles, a gap maybe formed between the second solder balls 17b or a gap may be formed in the solder paste 17c. Such a semiconductor module may also suppress EMI.

FIG. 8 illustrates a fourth modification of the embodiment.

As illustrated in FIG. 8, in the fourth modification, second lands 12c are arranged such that some of the second solder balls 17b are not brought into contact with each other. An interval L3 between some of the second lands 12c is set larger than the interval L2 illustrated in FIG. 1 and FIG. 2 within a range where the interval L3 is smaller than the first mutual interval L1 (L1>L3>L2).

In the semiconductor module having the configuration illustrated in FIG. 8, the second solder balls 17b are deformed in a state where the semiconductor module is mounted on a mother board. Accordingly, some of the second solder balls 17b are brought into contact with each other.

The fourth modification having the above-mentioned configuration may also suppress EMI.

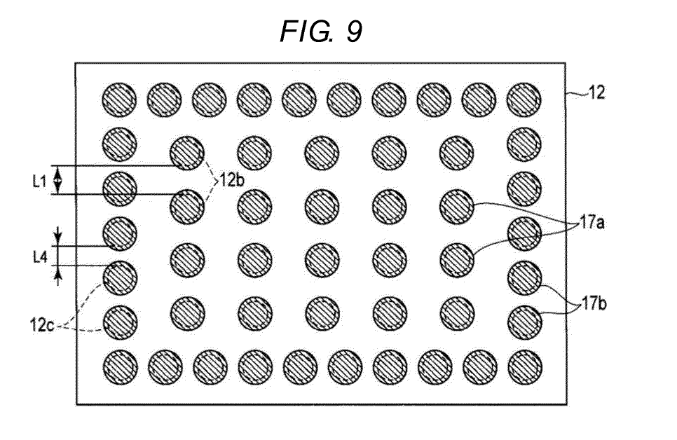

FIG. 9 illustrates a fifth modification of the embodiment.

As illustrated in FIG. 9, in the fifth modification, second lands 12c are arranged such that none of second solder balls 17b are brought into contact with each other. An interval L4 between the second lands 12c is set larger than the interval L2 illustrated in FIG. 1 and FIG. 2 and the interval L3 illustrated in FIG. 8 within a range where the mutual interval L4 is smaller than the mutual interval L1 (L1>L4>L3>L2).

In the semiconductor module having the configuration illustrated in FIG. 9, second solder balls 17b are deformed in a state where the semiconductor module is mounted on a mother board. Accordingly, portions of the second solder balls 17b are brought into contact with each other or none of second solder balls 17b are brought into contact with each other.

The fifth modification having the above-mentioned configuration may also suppress EMI.

While certain embodiments have been described, the embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus comprising:
a first substrate;
an electronic component mounted on a first surface of the first substrate;
a plurality of first lands on a second surface of the first substrate that is opposite the first surface, the first lands electrically connected to the electronic component and arranged at a first interval; and
a plurality of second lands on the second surface of the first substrate and surrounding the first lands, the second lands arranged at a second interval that is smaller than the first interval.

2. The electronic apparatus according to claim 1, further comprising:
a plurality of first solder balls provided on the first lands; and
a plurality of second solder balls provided on the second lands, each of the first and second solder balls having a same diameter, and at least two of the second solder balls are in contact with each other.

3. The electronic apparatus according to claim 2, further comprising:
a second substrate having a plurality of third lands arranged at the first interval and a plurality of fourth lands arranged at the second interval, wherein
the plurality of first solder balls are in contact with the third lands and electrically connect the first lands to the third lands, and
the plurality of second solder balls are in contact with the fourth lands and electrically connect the second lands to the fourth lands.

4. The electronic apparatus according to claim 3, wherein each of the second solder balls are in contact with adjacent second solder balls.

5. The electronic apparatus according to claim 3, further comprising:
a resin covering the electronic component, and
an electromagnetic shield covering the resin.

6. The electronic apparatus according to claim 5, wherein
the electromagnetic shield extends to the second surface of the first substrate and is in contact with the second lands.

7. The electronic apparatus according to claim 5, wherein
the electromagnetic shield extends past the second surface of the first substrate and is in contact with an extended portion of the fourth lands.

8. The electronic apparatus according to claim 1, wherein each of the second solder balls are in contact with adjacent second solder balls.

9. An electronic apparatus comprising:
a first substrate;
an electronic component mounted on a first surface of the first substrate;
a plurality of first lands on a second surface of the first substrate that is opposite the first surface, the first lands electrically connected to the electronic component and arranged at a first interval;
a plurality of second lands on the second surface of the first substrate and surrounding the first lands, the second lands arranged at a second interval that is smaller than the first interval.
a plurality of first solder balls provided on the first lands; and
a plurality of second solder balls provided on the second lands, each of the first and second solder balls having a same diameter.

10. The electronic apparatus according to claim 9, wherein the second solder balls surround the first lands in a rectangular pattern and the second solder balls at corners of the rectangular pattern are in contact with each other and other second solder balls are not in contact with each other.

11. The electronic apparatus according to claim 9, wherein none of the second solder balls are in contact with another second solder ball.

12. The electronic apparatus according to claim 11, further comprising:
a second substrate having a plurality of third lands arranged at the first interval and a plurality of fourth lands arranged at the second interval, wherein
the plurality of first solder balls are in contact with the third lands and electrically connect the first lands to the third lands, and
the plurality of second solder balls are in contact with the fourth lands and electrically connect the second lands to the fourth lands.

13. The electronic apparatus according to claim 12, further comprising:
a resin covering the electronic component, and
an electromagnetic shield covering the resin.

14. The electronic apparatus according to claim 13, wherein
the electromagnetic shield extends to the second surface of the first substrate and is in contact with the second lands.

15. The electronic apparatus according to claim 13, wherein
the electromagnetic shield extends past the second surface of the first substrate and is in contact with an extended portion of the fourth lands.

16. An electronic apparatus comprising:
a first substrate;
an electronic component mounted on a first surface of the first substrate;
a plurality of lands on a second surface of the first substrate that is opposite the first surface, the lands electrically connected to the electronic component; and
a continuously formed land pattern on the second surface of the first substrate and surrounding the lands.

17. The electronic apparatus according to claim 16, further comprising:
a plurality of solder balls provided on the lands; and
a continuously formed solder paste provided on the land pattern.

18. The electronic apparatus according to claim 17, further comprising:
a resin covering the electronic component, and
an electromagnetic shield covering the resin.

19. The electronic apparatus according to claim 18, wherein
the electromagnetic shield extends to the second surface of the first substrate and is in contact with the land pattern.

20. The electronic apparatus according to claim 19, wherein the electromagnetic shield and the land pattern are grounded.
